(19) United States
(12) Patent Application Publication
(10) Pub. No.: US 2024/0201229 A1
(43) Pub. Date: Jun. 20, 2024

(54) CURRENT SPECIFYING DEVICE

(71) Applicant: Traffic Sim Co.,Ltd., Nagoya-shi (JP)

(72) Inventors: Shoji SAWADA, Nagoya-shi (JP); Satoshi MIYAKE, Nagoya-shi (JP)

(73) Assignee: Traffic Sim Co.,Ltd., Nagoya-shi (JP)

(21) Appl. No.: 18/554,890

(22) PCT Filed: Jul. 12, 2022
(86) PCT No.: PCT/JP2022/027468

§ 371 Date: Oct. 11, 2023

(30) Foreign Application Priority Data
Jul. 15, 2021 (JP) 2021-117364

(51) Int. Cl. G01R 15/20; G01R 1/04; G01R 19/00; G01R 19/10

(52) U.S. Cl. CPC G01R 15/202; G01R 19/0038; G01R 19/10; G01R 1/04

(57) ABSTRACT

A current specifying device may comprise a plurality of sensors configured to be attached to an outer side of a sheath of a multicore cable, each of the plurality of sensors being configured to detect a magnetic field strength of a magnetic field generated by current flowing in the multicore cable, and a controller configured to specify a current value of the current flowing in the multicore cable by using the magnetic field strength detected by at least one sensor among the plurality of sensors, wherein the controller may detect a change in a relative relationship of the magnetic field strengths detected by at least two sensors among the plurality of sensors.

### CROSS-REFERENCE TO RELATED APPLICATION

This application is a related application of and claims priority to Japanese Patent Application No. 22021-117364 filed on Jul. 15, 2021, the entire contents of which are hereby incorporated by reference into the present application.

### TECHNICAL FIELD

The art disclosed in the description herein relates to an art configured to specify current flowing in a multicore cable.

### BACKGROUND ART

JP 2016-148597 A describes a current sensor that measures a current value of current flowing in a multicore cable in a contactless manner. The current sensor measures the current by detecting a magnetic field generated around a measurement target cable using a magnetic sensor element.

### SUMMARY OF INVENTION

### Technical Problem

In the above technique, a magnetic field strength changes in accordance with a distance between the sensor and a conductor in the multicore cable. In this case, for example, when a position of the sensor relative to the multicore cable changes, the magnetic field strength detected by the sensor changes even if the same current is flowing in the multicore cable. As a result, there may be a case in which the current value cannot suitably be specified using the magnetic field strength.

The description herein provides an art capable of identifying a situation in which current is not suitably specified using a magnetic field strength detected by a sensor.

### Solution to Technical Problem

The description herein discloses an art related to a current specifying device. The current specifying device comprises a plurality of sensors configured to be attached to an outer side of a sheath of a multicore cable, each of the plurality of sensors being configured to detect a magnetic field strength of a magnetic field generated by current flowing in the multicore cable, and a controller configured to specify a current value of the current flowing in the multicore cable by using the magnetic field strength detected by at least one sensor among the plurality of sensors, wherein the controller detects a change in a relative relationship of the magnetic field strengths detected by at least two sensors among the plurality of sensors.

For example, in a situation where positions of the plurality of sensors relative to the multicore cable do not change and the current can suitably be specified using the magnetic field strengths detected by the sensors, the relative relationship of the magnetic field strengths detected by the plurality of sensors does not change even when the current flowing in the multicore cable changes. In other words, in a situation where the relative relationship of the magnetic field strengths detected by the plurality of sensors changes, there is a possibility that a suitable current value cannot be specified using a magnetic field strength detected by a sensor. According to the above configuration, by detecting a change in the relative relationship of the magnetic field strengths detected by two sensors, a situation in which the current value is not suitably specified using the magnetic field strength detected by the sensor may be identified.

The description herein further discloses an art related to a sensor device. The sensor device comprise a plurality of sensors configured to be attached to an outer side of a sheath of a multicore cable, wherein each of the plurality of sensors is configured to detect a magnetic field strength of a magnetic field generated by current flowing in the multicore cable, and the plurality of sensors includes two or more sensors being arranged adjacent to each other about an axis of the multicore cable.

By using the sensor device as above the change in the relative relationship of the magnetic field strengths detected by two sensors can be detected, by which the situation in which the current value is not suitably specified using a magnetic field strengths detected by a sensor may be identified.

### BRIEF DESCRIPTION OF DRAWINGS

FIG. 1 shows a configuration of a current specifying device.

FIG. 2 shows a front view of a sensor unit.

FIG. 3 shows a front view of a sensor unit of a variant.

### DESCRIPTION OF EMBODIMENTS

Characteristics of the art disclosed in the description herein will be listed below. The respective characteristics as below are each independently useful.

The plurality of sensors may have fixed relative positions with respect to each other.

According to this configuration, a situation in which a current value is not suitably specified using a magnetic field strength detected by a sensor can be identified by detecting a change in the relative relationship of the magnetic field strengths detected by two sensors having fixed relative positions with respect to each other.

The controller may further comprise an output unit configured to output information based on the change in the relative relationship of the magnetic field strengths, the information being related to a position of at least one sensor among the plurality of sensors having been displaced.

When a position of a sensor relative to the multicore cable changes, the relative relationship of the magnetic field strengths between sensors changes. Due to this, a positional displacement of the sensors can be specified by detecting the change in the relative relationship of the magnetic field strengths. A user can check outputted information to acknowledge that the positional displacement of the sensors is occurring. Due to this, a situation in which a current value that was incorrectly specified in a state where the positions of the sensors were displaced is used can be avoided.

The at least two sensors may be arranged adjacent to each other about an axis of the multicore cable.

According to this configuration, a situation in which the positional displacement of the sensors cannot be specified despite the occurrence of the positional displacement between the sensors and the multicore cable can be suppressed.

A holder configured to house the plurality of sensors so that relative positions of the plurality of sensors do not change may be further comprised.

According to this configuration, the plurality of sensors can be fixed to the multicore cable by fixing the holder to the multicore cable.

The plurality of sensors may include a first sensor and a second sensor, and the controller may be configured to detect the change in the relative relationship of the magnetic field strengths by comparing a ratio of a magnetic field strength detected by the first sensor and a magnetic field strength detected by the second sensor at a first timing to a ratio of a magnetic field strength detected by the first sensor and a magnetic field strength detected by the second sensor at a second timing that is different from the first timing.

According to this configuration, by comparing the ratios of the magnetic field strengths at multiple timings, the change in the relative relationship of the magnetic field strengths can be detected without presetting a reference value.

### EMBODIMENTS

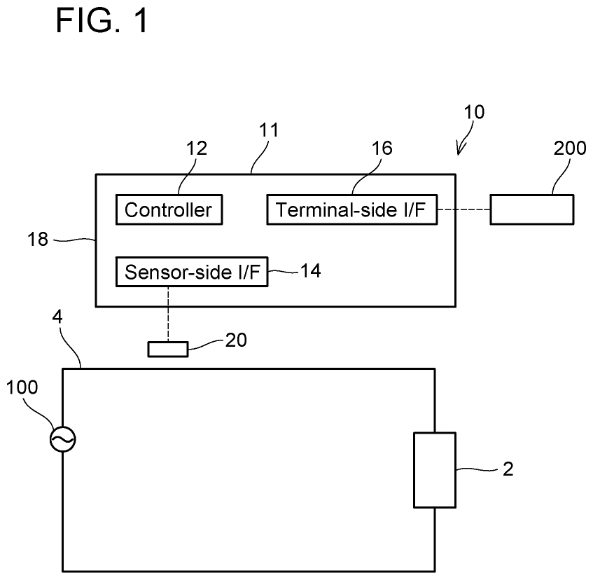

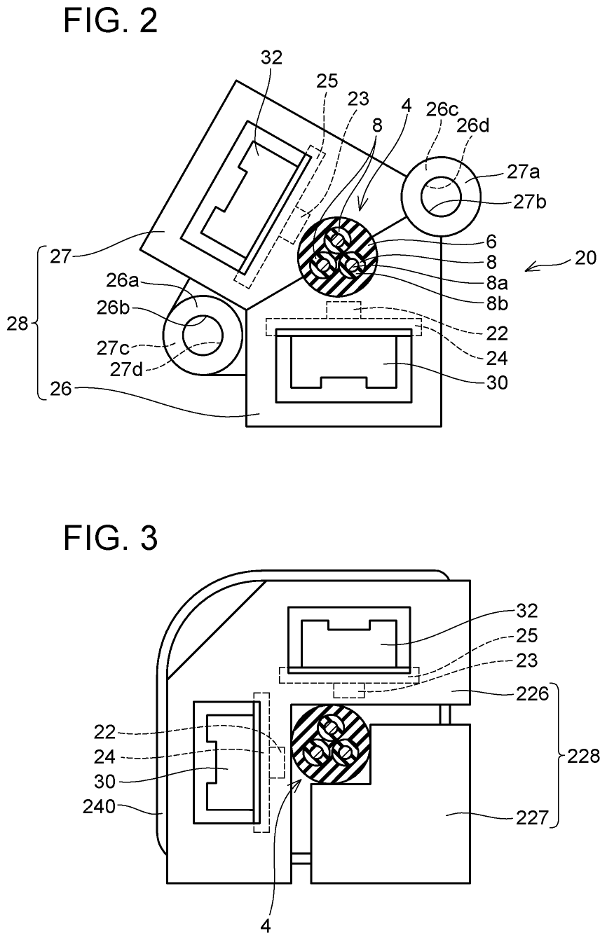

A current specifying device 10 of an embodiment will be described with reference to FIGS. 1 and 2. As shown in FIG. 1, the current specifying device 10 specifies a current value of current flowing in a multicore cable 4 connecting an AC power source 100 of a single-phase AC type and a target device 2. The current specifying device 10 comprises a processing device 11 and a sensor unit 20. The target device 2 is an electric device that receives electric power from the AC power source 100, and may for example be a rackmount server. The target device 2 is not limited to such, and may be any load such as an electric device.

As shown in FIG. 2, the multicore cable 4 comprises three cables 8 and a sheath 6 covering the three cables 8. Among the three cables 8, one cable 8 is grounded and the other two cables 8 are electrically conducted. The cables 8 each have a conductor 8a and an insulator 8b that covers the conductor 8a. In the multicore cable 4, the cables 8 are covered by the sheath 6, and how the three cables 8 are arranged is not visible from the outer appearance of the sheath 6.

The sensor unit 20 comprises a holder 28, circuit boards 24, 25, magnetic sensor modules 22, 23, two signal processing circuits (not shown), and connectors 30, 32. The circuit board 24 is a printed circuit board on which the magnetic sensor module 22, one signal processing circuit, and the connector 30 are mounted. The magnetic sensor module 22 is a Hall IC (Integrated Circuit) including a Hall element. The magnetic sensor module 22 is configured to output a voltage signal that changes in accordance with a magnetic field strength of a magnetic field generated around the magnetic sensor module 22. The signal processing circuit executes filtering process, AD conversion process, and the like to the voltage signal outputted from the magnetic sensor module 22 and outputs a processed signal. Each of the circuit board 25 and the magnetic sensor module 23 has a configuration similar to the corresponding one of the circuit board 24 and the magnetic sensor module 22. That is, the circuit board 25 has the magnetic sensor module 23, the other signal processing circuit, and the connector 32. The magnetic sensor modules 22, 23 are arranged adjacent to each other about an axis of the multicore cable 4. The magnetic sensor modules 22, 23 are arranged at a same position along an axial direction of the multicore cable 4.

In a variant, the magnetic sensor modules 22, 23 may include elements other than the Hall elements such as magnetic resistant elements. In this case, the circuit boards 24, 25 may have circuits conforming to signals outputted from such elements.

The connector 30 receives a cable that connects the circuit board 24 and the processing device 11. Similarly, the connector 32 receives a cable that connects the circuit board 25 and the processing device 11.

The circuit boards 24, 25, the magnetic sensor modules 22, 23, the signal processing circuits, and the connectors 30, 32 are housed in the holder 28. The holder 28 is configured by assembling two partial holders 26, 27. The partial holder 26 has a housing space that houses the circuit board 24, the magnetic sensor module 22, the one signal processing circuit, and the connector 30. The circuit board 24, the magnetic sensor module 22, the one signal processing circuit, and the connector 30 are fixed relative to the partial holder 26. The partial holder 27 has a housing space that houses the circuit board 25, the magnetic sensor module 23, the other signal processing circuit, and the connector 32. The circuit board 25, the magnetic sensor module 23, the other signal processing circuit, and the connector 32 are fixed relative to the partial holder 27.

The partial holder 26 includes a fixed piece 26a having a through hole 26b at its left end in FIG. 2. The partial holder 26 further includes a fixed piece 26c having a through hole 26d similar to the fixed piece 26a at its right end in FIG. 2. In FIG. 2, the fixed piece 26c is disposed overlapping a fixed piece 27a from behind this fixed piece 27a in a depthwise direction of the drawing at a right end of the partial holder 27 to be described later. The partial holder 27 includes the fixed piece 27a having a through hole 27b at its right end in FIG. 2. Further, it includes a fixed piece 27c having a through hole 27d similar to the fixed piece 27a at its left end in FIG. 2. In FIG. 2, the fixed piece 27c is disposed overlapping a fixed piece 26a from behind this fixed piece 26a in the depthwise direction of the drawing at the left end of the partial holder 26.

In the holder 28, the partial holders 26, 27 are arranged in contact with each other. In the holder 28, a through hole for placing and holding the multicore cable 4 therein is defined between the partial holders 26, 27. In a state where the partial holders 26, 27 contact each other, the fixed pieces 26a, 26c on the left and right sides of the partial holder 26 respectively overlap their corresponding fixed pieces 27a, 27c on the left and right sides of the partial holder 27. In this state, the through hole 26b and the through hole 27d are arranged to overlap and the through hole 26d and the through hole 27b are arranged to overlap, a pin penetrating through the through hole 26b and the through hole 27d is inserted, and a pin penetrating through the through hole 26d and the through hole 27b is inserted. Due to this, the holder 28 is fixed to the multicore cable 4 by the partial holders 26, 27 holding the multicore cable 4 therebetween.

The sensor unit 20 is connected to the processing device 11 via a cable. The processing device 11 comprises a controller 12, a sensor-side interface 14, a terminal-side interface 16, and a case 18. In the drawing and the description below, an “interface” will be termed “I/F”. The controller 12, the sensor-side I/F 14, and the terminal-side I/F 16 are housed in a casing 18. The controller 12 is communicably connected to the sensor-side I/F 14 and to the terminal-side I/F 16 via bus lines. A cable extending from the sensor unit 20 is connected to the sensor-side I/F 14. The sensor-side I/F 14 is configured to obtain signals outputted from the sensor unit 20 and supply the same to the controller 12.

The controller 12 includes a CPU and a memory. The controller 12 is configured to execute various processes according to a program stored in the memory. Processes executed by the controller 12 will be described later.

The terminal-side I/F 16 is a wired interface and/or a wireless interface, and is communicably connected to a user terminal 200 (such as a PC or a portable terminal). The terminal-side I/F 16 is configured to send information supplied from the controller 12 to the terminal connected to the terminal-side I/F 16.

### (Current Value Specifying Method)

Next, a method by which the current specifying device 10 specifies a current value of current flowing in the multicore cable 4 will be described. The controller 12 specifies a current value at a timing at which the current value should be specified. The timing at which the current value should be specified may for example be a timing when the processing device 11 receives, via the terminal-side I/F 16, a current specifying request sent from the terminal 200 as a result of a user operating the terminal 200, or may be a preset cyclic timing.

The controller 12 obtains a signal related to a magnetic field strength detected by the magnetic sensor module 22 from the sensor unit 20 at the timing at which the current value should be specified. Then, the controller 12 specifies the current value from the obtained signal by using a conversion equation stored in the memory in advance. Then, it sends the specified current value to the terminal 200 via the terminal-side I/F 16. When the current value obtained from the processing device 11 is obtained, the terminal 200 displays the current value on a display unit.

### (Positional Displacement Detection Process)

Next, a positional displacement detection process for the sensor unit 20 executed by the current specifying device 10 will be described. The controller 12 obtains signals related to magnetic field strengths detected by the magnetic sensor modules 22, 23 at a timing when the sensor unit 20 is mounted on the multicore cable 4. Then, the controller 12 calculates a ratio X2/X1 of a detected value X2 of the magnetic sensor module 23 relative to a detected value X1 of the magnetic sensor module 22, and stores the same in the memory.

When a timing to detect a positional displacement arrives, the controller 12 obtains signals related to magnetic field strengths detected in the magnetic sensor modules 22, 23. Then, the controller 12 calculates a ratio X4/X3 of a detected value X4 of the magnetic sensor module 23 relative to a detected value X3 of the magnetic sensor module 22. Then, the controller 12 determines whether the ratio X2/X1 and the ratio X4/X3 match each other. A state in which the ratio X2/X1 and the ratio X4/X3 match includes not only a state in which the ratio X2/X1 and the ratio X4/X3 match completely, but also states in which they deviate from one another within a predetermined range (such as +5%), for example.

The timing to detect a positional displacement may for example be same as the timing at which the current value should be specified, or may be a timing when the processing device 11 receives, via the terminal-side I/F 16, a positional displacement detection request sent from the terminal 200 as a result of the user operating the terminal 200, or may be a preset cyclic timing.

The controller 12 sends the terminal 200 information indicating that no positional displacement is occurring in a case of determining that the ratio X2/X1 and the ratio X4/X3 match. On the other hand, in a case of determining that the ratio X2/X1 and the ratio X4/X3 do not match, it sends the terminal 200 information indicating that a positional displacement is occurring. The terminal 200 displays an image representing information received from the processing device 11 on the display unit of the terminal 200. Due to this, the user can acknowledge whether a position of the sensor unit 20 is displaced.

In the current specifying device 10, the controller 12 converts the magnetic field strength detected by the magnetic sensor module 22 into a current value using the conversion equation. The conversion equation is defined in advance from a correlation of the magnetic field strength and the current value. However, the correlation of the magnetic field strength and the current value changes according to a distance between the magnetic sensor module 22 and the conductor 8a. Due to this, when a positional relationship of the sensor unit 20 and the multicore cable 4 changes, the current value may not be suitably specified in some cases from the magnetic field strength detected by the magnetic sensor module 22 using the predefined conversion equation.

When the positional relationship of the sensor unit 20 and the multicore cable 4 changes, the distance between the magnetic sensor module 22 and the conductor 8a and a distance between the magnetic sensor module 23 and the conductor 8a may thereby change in some cases. As a result, a relative relationship of the magnetic field strength detected by the magnetic sensor module 22 and the magnetic field strength detected by the magnetic sensor module 23 changes. In the current specifying device 10, the determination on whether or not the relative relationship of the magnetic field strengths detected by the magnetic sensor modules 22, 23 has changed is made by comparing the ratio X2/X1 and the ratio X4/X3. Due to this, the determination on whether or not the positional relationship of the sensor unit 20 and the multicore cable 4 has changed can be made. As a result of this, a situation in which the current value is specified in a state where the current value cannot suitably be specified from the magnetic field strength despite using the predefined conversion equation can be avoided.

In the sensor unit 20, the magnetic sensor modules 22, 23 are arranged adjacent to each other about the axis of the multicore cable 4. According to this configuration, a situation in which the ratio X2/X1 and the ratio X4/X3 do not change due to the relative relationship of the distance between the magnetic sensor module 22 and the conductor 8a and the distance between the magnetic sensor module 23 and the conductor 8a not having changed despite a correlation of the magnetic field strength from the magnetic sensor module 22 and the current value having changed due to the positional displacement between the sensor unit 20 and the multicore cable 4 is less likely to happen. Due to this, the positional displacement between the sensor unit 20 and the multicore cable 4 can suitably be specified.

In the sensor unit 20, the holder 28 holds the plurality of magnetic sensor modules 22, 23 so that their relative positions do not change. As a result, the plurality of magnetic sensor modules 22, 23 can be fixed to the multicore cable 4 by fixing the holder 28 to the multicore cable 4.

The holder 28 clamps the multicore cable 4 and is fixed to the multicore cable 4 by assembling the partial holders 26, 27. According to this configuration, the holder 28 can easily be fixed to the multicore cable 4.

In the current specifying device 10, the change in the relative relationship of the magnetic field strengths is detected by comparing the ratio X2/X1 and the ratio X4/X3. According to this configuration, the relative relationship of the magnetic field strengths does not need to be specified in advance. The ratio to be compared with the newest ratio X4/X3 may not be the ratio detected immediately before the newest ratio X4/X3. It may be a ratio of magnetic field strengths that are detected just after having fixed the sensor unit 20 to the multicore cable 4, or may be predefined.

Specific examples of the embodiments described herein have been described, however, these are mere exemplary indications and thus do not intend to limit the scope of the claims. These embodiments can be implemented in various other configurations, and various omissions, substitutions, and modifications can be made within the scope that does not go beyond the essence of the invention.

The number of the plurality of magnetic sensor modules 22, 23 provided in the sensor unit 20 is not limited, and three or more magnetic sensor modules may be disposed. In this case, the current specifying device 10 may specify the current value of the current flowing in the multicore cable 4 by using magnetic field strength(s) detected by one or more magnetic sensor modules among the three or more magnetic sensor modules. Further, the change in the relative relationship of the magnetic field strengths may be detected by using magnetic field strengths detected by two or more magnetic sensor modules among the three or more magnetic sensor modules.

The configuration of the holder that holds the plurality of magnetic sensor modules 22, 23 is not limited to the holder 28. For example, a holder 228 shown in FIG. 3 may comprise a partial holder 226 and a partial holder 227 arranged facing the partial holder 226 with the multicore cable 4 interposed in between them. The partial holder 226 may house the plurality of magnetic sensor modules 22, 23, the circuit boards 24, 25, the signal processing circuits, and the connectors 30, 32. The partial holder 226 and the partial holder 227 may be fixed relative to the multicore cable 4 by being tied by a tying band 240 in a state of having the multicore cable 4 held in between them.

The plurality of magnetic sensor modules 22, 23 may be configured capable of changing the relative positions relative to each other. For example, when the magnetic sensor module 22 changes its position relative to the multicore cable 4 but the magnetic sensor module 23 does not change its position relative to the multicore cable 4, the relative relationship of the magnetic field strengths detected by the magnetic sensor modules 22, 23 may change. Due to this, the displacement(s) of the positions of the magnetic sensor modules 22, 23 relative to the multicore cable 4 can be specified using the change in the relative relationship of the magnetic field strengths detected by the magnetic sensor modules 22, 23.

The AC power source 100 may not be a single-phase AC type, and may for example be a three-phase AC type. In this case, the multicore cable 4 may have two or more cables 8 covered by the sheath 6 to correspond to the AC power source 100.

These embodiments and variants thereof are included in the scope of the claims and the essence thereof, and are also encompassed by the inventions recited in the claims and their equivalents.

### REFERENCE SIGNS LIST

2: target device, 4: multicore cable, 6: sheath, 8: cables 8a: conductor, 10: current specifying device, 11: processing device, 12: controller, 20: sensor unit, 22, 23: magnetic sensor module, 26, 27: partial holder, 28: holder, 100: AC power source

1. A current specifying device comprising:
a plurality of sensors configured to be attached to an outer side of a sheath of a multicore cable, each of the plurality of sensors being configured to detect a magnetic field strength of a magnetic field generated by current flowing in the multicore cable; and
a controller configured to specify a current value of the current flowing in the multicore cable by using the magnetic field strength detected by at least one sensor among the plurality of sensors,
wherein the controller detects a change in a relative relationship of the magnetic field strengths detected by at least two sensors among the plurality of sensors.

2. The current specifying device according to claim 1, wherein the plurality of sensors has fixed relative positions with respect to each other.

3. The current specifying device according to claim 1, wherein the controller further comprises an output unit configured to output information based on the change in the relative relationship of the magnetic field strengths, the information being related to a position of at least one sensor among the plurality of sensors having been displaced.

4. The current specifying device according to claim 1, wherein the at least two sensors are arranged adjacent to each other about an axis of the multicore cable.

5. The current specifying device according to claim 1, further comprising a holder configured to house the plurality of sensors so that relative positions of the plurality of sensors do not change.

6. The current specifying device according to claim 1, wherein
the plurality of sensors includes a first sensor and a second sensor, and
the controller is configured to detect the change in the relative relationship of the magnetic field strengths by comparing a ratio of a magnetic field strength detected by the first sensor and a magnetic field strength detected by the second sensor at a first timing to a ratio of a magnetic field strength detected by the first sensor and a magnetic field strength detected by the second sensor at a second timing that is different from the first timing.

7. The current specifying device according to claim 1, wherein
the plurality of sensors includes a first sensor and a second sensor, and
the controller further comprises an output unit configured to output information by comparing a ratio of a magnetic field strength detected by the first sensor and a magnetic field strength detected by the second sensor at a first timing to a ratio of a magnetic field strength detected by the first sensor and a magnetic field strength detected by the second sensor at a second timing that is different from the first timing, the information indicating that a displacement of a position of a specific sensor which is at least one of the first and second sensors at the second timing from a position of the specific sensor at the first timing is occurring.
